(19) United States
(12) Patent Application Publication
(10) Pub. No.: US 2025/0308935 A1
(43) Pub. Date: Oct. 2, 2025

(54) METHOD FOR FABRICATING A PACKAGE SUBSTRATE

(71) Applicant: AaltoSemi Inc., Nanjing City (CN)

(72) Inventors: Yin-Ju Chen, Nanjing City (CN); Sung-Kun Lin, Nanjing City (CN); De-Long Liu, Nanjing City (CN); Yang-Li Wu, Nanjing City (CN); Min-Yao Chen, Nanjing City (CN); Andrew C. Chang, Nanjing City (CN)

(73) Assignee: AaltoSemi Inc., Nanjing City (CN)

(21) Appl. No.: 19/092,136

(22) Filed: Mar. 27, 2025

(30) Foreign Application Priority Data
Mar. 27, 2024 (CN) 202410362357.8

(51) Int. Cl. H01L 21/48; H01L 23/544

(52) U.S. Cl. CPC H01L 21/4857; H01L 21/486; H01L 23/544; H01L 2223/54426

(57) ABSTRACT

A method of fabricating a package substrate is provided. The method is to stack and bond a first substrate body and a second substrate body by a bonding layer and a release layer to increase the overall thickness, so that the limitations of general processing equipment on substrate thickness can be overcome.

### CROSS-REFERENCE TO RELATED APPLICATION

This application claims the benefit of priority to Chinese Patent Application No. 202410362357.8, filed Mar. 27, 2024, the entire contents of which are hereby incorporated by reference.

### BACKGROUND

### 1. Technical Field

The present disclosure relates to a semiconductor packaging process, and in particular refers to a method of fabricating a package substrate that meets the thinness requirement.

### 2. Description of Related Art

With the booming development of the electronics industry, many high-end electronic products are gradually developed along directions of higher integration such as being lighter, thinner, shorter and smaller. In addition, with the evolution of packaging technology, semiconductor chip packaging technology is also becoming more and more diversified, and sizes or volumes of package substrates are also constantly shrinking, in order to achieve the purpose of lighter, thinner, shorter and smaller semiconductor packages.

FIG. 1 is a schematic cross-sectional diagram of a conventional package substrate 1. As shown in FIG. 1, the package substrate 1 includes a core layer 10, circuit structures 11 disposed on both sides of the core layer 10, and solder masks 12 formed on the circuit structures 11, wherein the core layer 10 has conductive pillars 100 that are penetrating through the core layer 10 and are electrically connected to wire layers 110 of the circuit structures 11. Each of the circuit structures 11 further includes at least one dielectric layer 111 encapsulating the wire layers 110. The outermost wire layers 110 of the circuit structures 11 are exposed from the solder masks 12 and serve as connection points 112 (i.e., input/output terminals or I/O terminals) for accessing semiconductor chips.

In the fabrication of the conventional package substrate 1, a thinner package substrate is required for a package-on-package (POP) structure as an interposer coupled to the substrate via solder balls, which in turn is required to be thinner (<100 μm), with lower warpage (<0.1 mm), with high density patterns (L/S=15/15 μm, where L/S stands for line width and spacing) and with laser vias (≤50 μm).

However, since thin package substrates produced by general processing equipment (with the limitation of substrate thickness≥0.1 mm) are prone to generating the risk of damage, their processability is limited, resulting in the need to use unique and expensive processing equipment throughout the entire process to fabricate the thin package substrates, which leads to a significant increase in the cost of production.

Therefore, the need to overcome the aforementioned problems of the prior art has become an urgent issue.

### SUMMARY

In view of the aforementioned deficiencies of the prior art, the present disclosure provides a method of fabricating a package substrate, the method comprises: providing a bonding layer, a first substrate body and a second substrate body, wherein each of the first substrate body and the second substrate body has a first surface and a second surface opposite to the first surface; disposing the first substrate body and the second substrate body on both sides of the bonding layer by the second surface of the first substrate body and the second surface of the second substrate body, respectively; forming a plurality of conductors in the first substrate body and the second substrate body; forming a first patterned wire layer on each of the first surfaces of the first substrate body and the second substrate body, wherein the first patterned wire layers are electrically connected to the plurality of conductors; separating the first substrate body, the second substrate body and the bonding layer; bonding the first substrate body and the second substrate body to two opposite sides of a release layer via the first surface of the first substrate body and the first surface of the second substrate body, respectively; forming a second patterned wire layer on each of the second surfaces of the first substrate body and the second substrate body, wherein the second patterned wire layers are electrically connected to the plurality of conductors; and separating the first substrate body, the second substrate body and the release layer to obtain the package substrates.

In an exemplary embodiment of the present disclosure, each of the first substrate body and the second substrate body comprises a core layer, first metal layers formed on both sides of the core layer, and second metal layers formed on the first metal layers.

In an exemplary embodiment of the present disclosure, the method of fabricating the package substrate further comprises searing the first metal layers, the second metal layers and parts of the core layers at peripheries of the second surfaces of the first substrate body and the second substrate body to form a sealed channel.

In an exemplary embodiment of the present disclosure, the method of fabricating the package substrate further comprises forming a plurality of first vias at peripheries of the first substrate body and the second substrate body, and forming a plurality of second vias at peripheries of the bonding layer corresponding to positions of the plurality of first vias, so as to penetrate through the plurality of first vias and the plurality of second vias by means of pins of a pinning fixture, in order to dispose the first substrate body and the second substrate body on the both sides of the bonding layer by the second surface of the first substrate body and the second surface of the second substrate body, respectively.

In an exemplary embodiment of the present disclosure, when the sealed channel is formed at peripheries of the second surfaces of the first substrate body and the second substrate body, the method of fabricating the package substrate further comprises forming a plurality of first vias at peripheries of the first substrate body and the second substrate body outside the sealed channel, and forming a plurality of second vias at peripheries of the bonding layer corresponding to positions of the plurality of first vias, so as to penetrate through the plurality of first vias and the plurality of second vias by means of pins of a pinning fixture, in order to dispose the first substrate body and the second substrate body on the both sides of the bonding layer by the second surface of the first substrate body and the second surface of the second substrate body, respectively.

In an exemplary embodiment of the present disclosure, the step of bonding the first substrate body and the second substrate body that are separated to the both sides of the release layer by the first surface of the first substrate body and the first surface of the second substrate body respectively comprises forming a plurality of third vias at peripheries of the first substrate body and the second substrate body, and forming a plurality of fourth vias at peripheries of the release layer corresponding to positions of the plurality of third vias, so as to penetrate through the plurality of third vias and the plurality of fourth vias by means of pins of a pinning fixture, in order to bond the release layer and the first substrate body and the second substrate body that are separated.

In an exemplary embodiment of the present disclosure, the method of fabricating the package substrate further comprises laminating the release layer and the first substrate body and the second substrate body that are separated by the release layer. In an exemplary embodiment of the present disclosure, the laminating is performed by a roller to laminate the release layer and the first substrate body and the second substrate body that are separated by the release layer.

In an exemplary embodiment of the present disclosure, the method of fabricating the package substrate further comprises forming a plurality of first alignment marks at peripheries of the second surfaces of the first substrate body and the second substrate body for disposing the first substrate body and the second substrate body on the both sides of the bonding layer by the second surface of the first substrate body and the second surface of the second substrate body, respectively.

In an exemplary embodiment of the present disclosure, when the sealed channel is formed at peripheries of the second surfaces of the first substrate body and the second substrate body, the method of fabricating the package substrate further comprises forming a plurality of first alignment marks at peripheries of the second surfaces of the first substrate body and the second substrate body outside the sealed channel for disposing the first substrate body and the second substrate body on the both sides of the bonding layer by the second surface of the first substrate body and the second surface of the second substrate body, respectively.

In an exemplary embodiment of the present disclosure, the plurality of first alignment marks are used as positioning marks for bonding the first substrate body and the second substrate body.

In an exemplary embodiment of the present disclosure, the method of fabricating the package substrate further comprises after forming the first patterned wire layer on the first surface of each of the first substrate body and the second substrate body, forming a plurality of second alignment marks at peripheries of the first surfaces of the first substrate body and the second substrate body for disposing the first substrate body and the second substrate body that are separated on the both sides of the release layer by the first surface of the first substrate body and the first surface of the second substrate body, respectively.

In an exemplary embodiment of the present disclosure, the plurality of second alignment marks are used as positioning marks for bonding the first substrate body and the second substrate body, so as to stack the first substrate body and the second substrate body on the both sides of the release layer by the first surface of the first substrate body and the first surface of the second substrate body, respectively, and then laminate the release layer and the first substrate body and the second substrate body that are separated.

In an exemplary embodiment of the present disclosure, the method of fabricating the package substrate further comprises forming a first insulation layer having a plurality of openings on each of the first patterned wire layers, wherein parts of the first patterned wire layers are exposed from the plurality of openings.

In an exemplary embodiment of the present disclosure, the method of fabricating the package substrate further comprises forming a surface treatment layer on each of the first patterned wire layers exposed from the plurality of openings of the first insulation layers.

In an exemplary embodiment of the present disclosure, the method of fabricating the package substrate further comprises forming a second insulation layer having a plurality of openings on each of the second patterned wire layers, wherein parts of the second patterned wire layers are exposed from the plurality of openings.

In view of the above, the method of fabricating the package substrate of the present disclosure stacks and bonds two thin substrate bodies, namely the first substrate body and the second substrate body, through the bonding layer and the release layer, so as to increase the overall thickness, thereby overcoming the processing limitations of general processing equipment and providing general processing equipment with processing capability.

### BRIEF DESCRIPTION OF THE DRAWINGS

FIG. 1 is a schematic cross-sectional diagram of a conventional semiconductor package according to the prior art.

FIG. 2A, FIG. 2B, FIG. 2C, FIG. 2D, FIG. 2E, FIG. 2F, FIG. 2G, FIG. 2H-1, FIG. 2I and FIG. 2J are schematic cross-sectional diagrams illustrating an exemplary method of fabricating a package substrate according to the first embodiment of the present disclosure.

FIG. 2H-2 is a schematic cross-sectional diagram illustrating the roller lamination of the present disclosure.

FIG. 3A to FIG. 3K are schematic cross-sectional diagrams illustrating an exemplary method of fabricating a package substrate according to the second embodiment of the present disclosure.

### DETAILED DESCRIPTION

The following examples are used for illustrating the present disclosure. A person skilled in the art can easily conceive the other advantages and effects of the present disclosure, based on the disclosure of the specification.

It should be noted that the structures, proportions, sizes, etc., shown in the drawings attached to this specification are only for the purpose of matching the contents of the specification for understanding and reading by those skilled in the art, and are not intended to limit the conditions under which the present disclosure may be implemented, and therefore do not have technical significance, and any modification of the structures, change of the proportions, or adjustment of the sizes shall remain within the scope of the technical contents of the present disclosure, provided that the effects and purposes that the present disclosure can produce and achieve are not affected. At the same time, the terms such as “on,” “first,” “second,” “a,” “one,” etc. quoted in the specification are only for the purpose of clarity of description and are not intended to limit the scope of implementation of the present disclosure, and any changes or adjustments in the relative relations thereof shall be considered to be within the scope of implementation of the present disclosure in the absence of substantive changes in the technical contents.

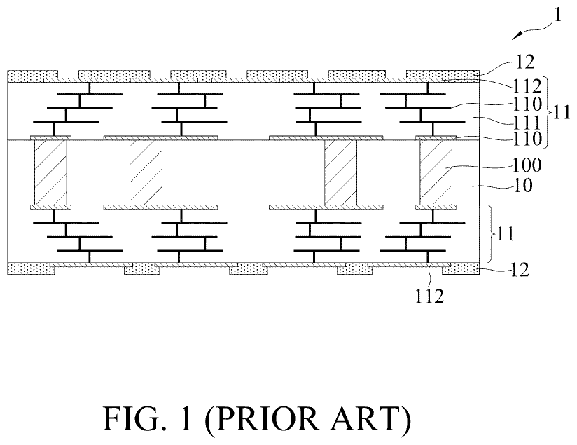

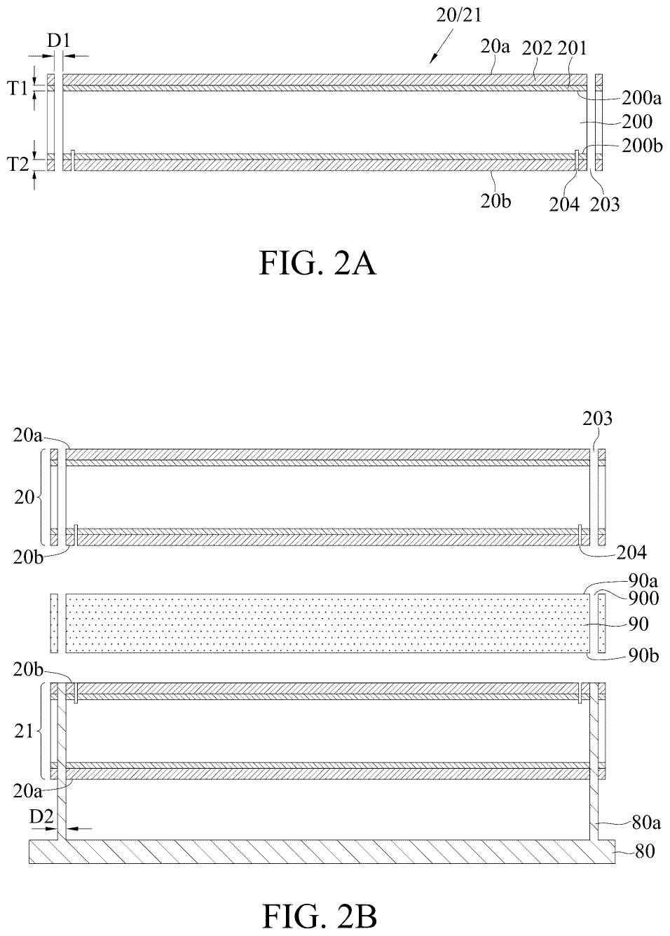

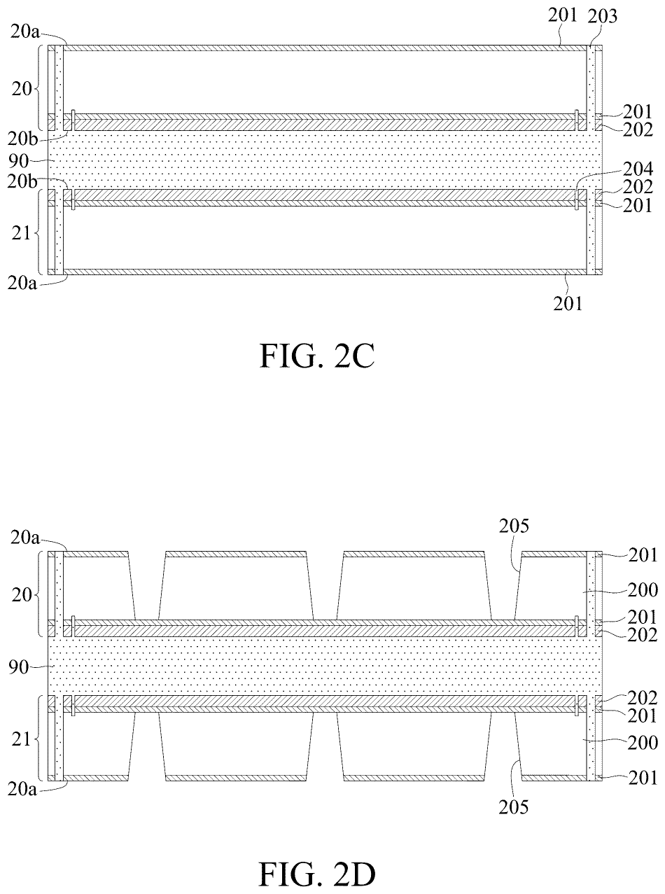

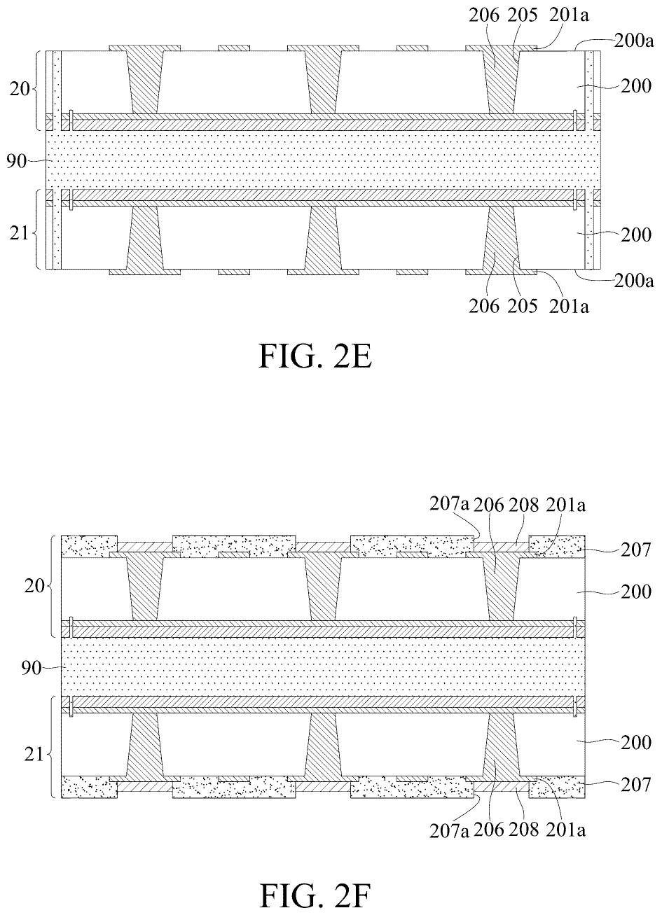

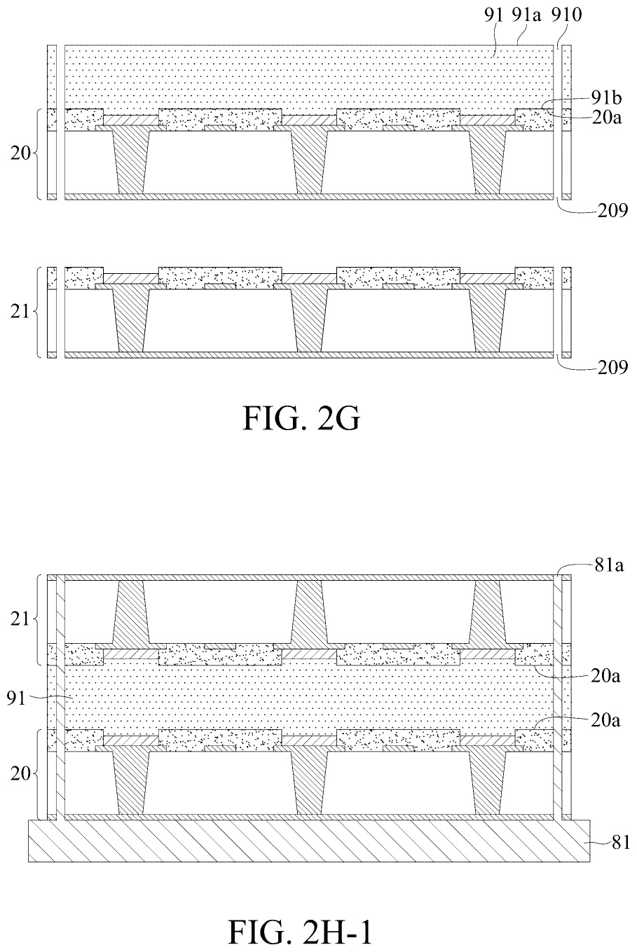

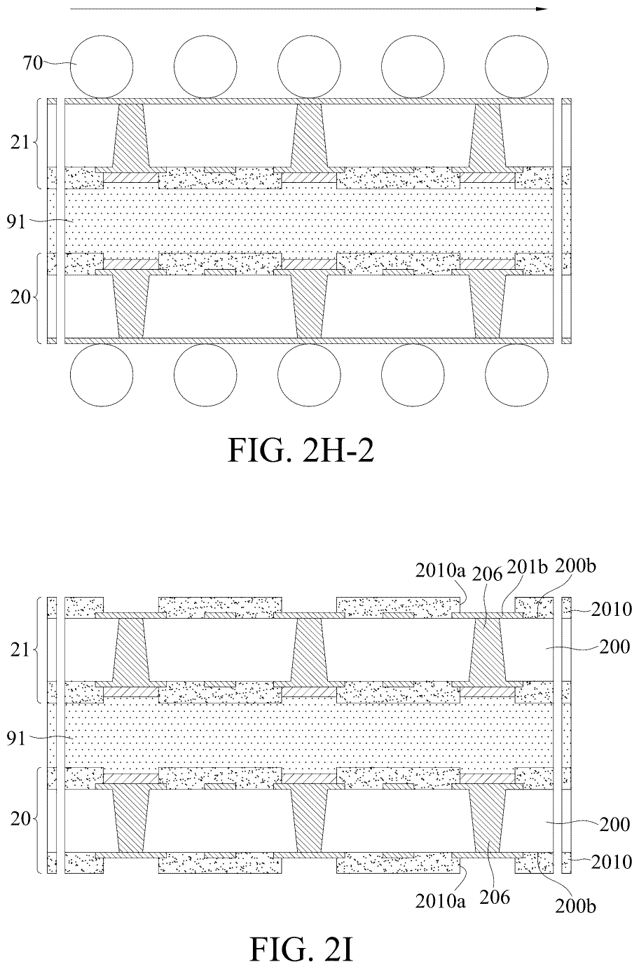

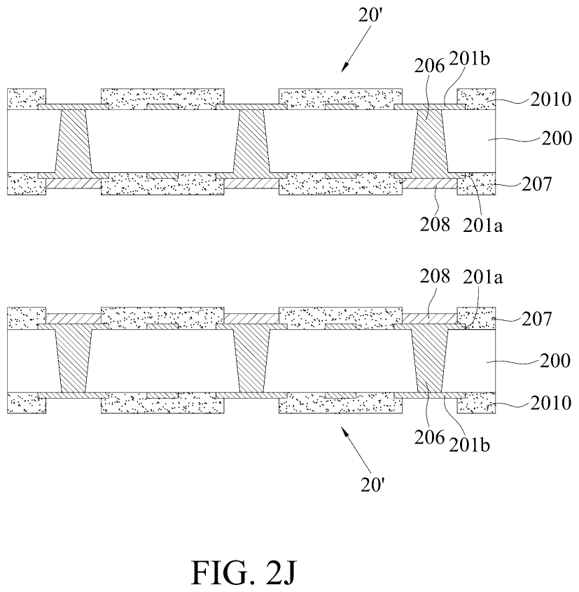

FIG. 2A, FIG. 2B, FIG. 2C, FIG. 2D, FIG. 2E, FIG. 2F, FIG. 2G, FIG. 2H-1, FIG. 2I and FIG. 2J are schematic cross-sectional diagrams illustrating an exemplary method of fabricating a package substrate according to the first embodiment of the present disclosure.

As shown in FIG. 2A, a first substrate body 20 and a second substrate body 21 with a plurality of first vias 203 (e.g., first through-vias) and a sealed channel 204 are provided.

In an exemplary embodiment, each of the first substrate body 20 and the second substrate body 21 has a first surface 20a and a second surface 20b opposite to the first surface 20a. Further, each of the first substrate body 20 and the second substrate body 21 includes a core layer 200 having opposite first and second sides 200a and 200b, first metal layers 201 formed on the first side 200a and the second side 200b, and second metal layers 202 formed on the first metal layers 201, wherein the core layer 200 is a substrate formed by, for example, glass fibers with epoxy, such as dielectric material such as bismaleimide triazine (BT) or FR5 (FR stands for flame retardant). The material of the first metal layers 201 and the second metal layers 202 is, for example, copper (Cu).

In an exemplary embodiment, the first surface 20a and the second surface 20b of the first substrate body 20 and the second substrate body 21 are penetrated by, for example, laser or mechanical drilling to form the plurality of first vias 203 at the periphery of the first substrate body 20 and the second substrate body 21. Specifically, the first vias 203 penetrate through the core layer 200, the first metal layers 201 and the second metal layers 202.

In an exemplary embodiment, the annular sealed channels 204 are formed at the peripheries of the second surfaces 20b of the first substrate body 20 and the second substrate body 21, and the sealed channels 204 are disposed inside the first vias 203. For example, the first metal layer 201, the second metal layer 202 and a portion of the core layer 200 (i.e., a portion of the core layer 200 in contact with the first metal layer 201) are sealed by laser searing on the second surface 20b to form the sealed channel 204, so as to strengthen the sealing of the first metal layer 201, the second metal layer 202 and the core layer 200 through the sealed channel 204 to avoid short-circuiting caused by liquid permeation in the subsequent fabrication process.

In an exemplary embodiment, the thickness T1 of the first metal layer 20 is less than the thickness T2 of the second metal layer 202. For example, the thickness T1 of the first metal layer 20 is about 3 μm, and the thickness T2 of the second metal layer 202 is about 18 μm.

As shown in FIG. 2B, a bonding layer 90 having a first side 90a and a second side 90b opposite to the first side 90a is provided, and the first substrate body 20 and the second substrate body 21 are respectively disposed on the first side 90a and the second side 90b of the bonding layer 90 by means of a first pinning fixture 80.

Specifically, the bonding layer 90 has a plurality of second vias 900 (e.g., second through-vias) whose positions correspond to the positions of the first vias 203. The second surface 20b of the first substrate body 20 is disposed on the first side 90a of the bonding layer 90, and the second surface 20b of the second substrate body 21 is disposed on the second side 90b of the bonding layer 90, wherein the first vias 203 of the first substrate body 20 and the second substrate body 21 correspond to the second vias 900 of the bonding layer 90, so that pins 80a of the first pinning fixture 80 penetrate through the first vias 203 of the first substrate body 20 and the second substrate body 21 and the second vias 900 of the bonding layer 90 to stack the first substrate body 20, the second substrate body 21 and the bonding layer 90.

In an exemplary embodiment, the width D1 of the first vias 203 of the first substrate body 20 and the second substrate body 21 and the second vias 900 of the bonding layer 90 is slightly larger than the width D2 of the pins 80a of the first pinning fixture 80.

In an exemplary embodiment, the material of the bonding layer 90 may be selected from dielectric materials such as prepreg (PP), Ajinomoto build-up film (ABF), photoimageable dielectric (PID), or polyimide (PI), and the material of the bonding layer 90 is not limited to the above types of materials.

As shown in FIG. 2C, after withdrawing the pins 80a of the first pinning fixture 80, the first substrate body 20, the second substrate body 21 and the bonding layer 90 are laminated so that the second surfaces 20b of the first substrate body 20 and the second substrate body 21 are disposed on both sides of the bonding layer 90, and then the second metal layers 202 on the first surfaces 20a of the first substrate body 20 and the second substrate body 21 are removed.

In this exemplary embodiment, the material of the bonding layer 90 is caused to fill the first vias 203 of the first substrate body 20 and the second substrate body 21 (the material of the bonding layer 90 may even fill the sealed channels 204) by using lamination.

As shown in FIG. 2D, a plurality of blind holes 205 are formed in the first substrate body 20 and the second substrate body 21.

In this exemplary embodiment, on the first surfaces 20a of the first substrate body 20 and the second substrate body 21, parts of the first metal layers 201 and the core layers 200 are removed by mechanical, laser, etching, or other appropriate means to form the blind holes 205.

As shown in FIG. 2E, a plurality of conductors 206 are formed in the blind holes 205, and first patterned wire layers 201a are formed on the first sides 200a of the core layers 200 of the first substrate body 20 and the second substrate body 21, and the first patterned wire layers 201a are electrically connected to the conductors 206.

In this exemplary embodiment, the conductors 206 are formed in the blind holes 205 by electroplating. The conductors 206 are formed to be flush with the first metal layers 201, and then the first metal layers 201 are etched by patterning process to form the first patterned wire layers 201a on the first sides 200a of the core layers 200 of the first substrate body 20 and the second substrate body 21.

As shown in FIG. 2F, first insulation layers 207 with a plurality of first openings 207a are formed on the first patterned wire layers 201a, and parts of the first patterned wire layers 201a are exposed through the first openings 207a, and surface treatment layers 208 are formed in the first openings 207a, and the surface treatment layers 208 are electrically connected to the first patterned wire layers 201a.

In this exemplary embodiment, the surface treatment layers 208 are formed by electroplating in the first openings 207a of the first insulation layers 207 by means of electroless nickel immersion gold (ENIG), wherein the material forming the surface treatment layers 208 is a nickel-gold alloy (Ni/Au), and the material forming the first insulation layers 207 is an epoxy such as green solder mask or green paint (solder-resist material).

In an exemplary embodiment, the peripheries of the first substrate body 20, the second substrate body 21 and the bonding layer 90 are cut off to remove the first vias 203 and the second vias 900.

As shown in FIG. 2G, the first substrate body 20, the second substrate body 21 and the bonding layer 90 are separated. Specifically, the bonding layer 90 and the second metal layers 202 on the second surfaces 20b of the first substrate body 20 and the second substrate body 21 are removed, and then a release layer 91 (e.g., a thermal released film or TRF) is formed on the first surface 20a of the first substrate body 20.

In this exemplary embodiment, the first surfaces 20a and the second surfaces 20b of the first substrate body 20 and the second substrate body 21 are penetrated through to form a plurality of third vias 209 (e.g., third through-vias) at the peripheries of the first substrate body 20 and the second substrate body 21. For example, the core layers 200, the first metal layers 201, the first patterned wire layers 201a and the first insulation layers 207 are penetrated through by techniques such as laser or mechanical drilling to form the third vias 209.

In an embodiment, the release layer 91 has a first side 91a and a second side 91b opposite to the first side 91a. A plurality of fourth vias 910 (e.g., fourth through-vias) are formed corresponding to the positions of the third vias 209 by penetrating through the first side 91a and the second side 91b of the release layer 91. Further, the second side 91b of the release layer 91 is disposed on the first surface 20a of the first substrate body 20.

As shown in FIG. 2H-1, the second substrate body 21 is disposed on the release layer 91, and the first substrate body 20 and the second substrate body 21 that are separated are respectively disposed on the first side 91a and the second side 91b of the release layer 91 by a second pinning fixture 81.

In this exemplary embodiment, the first surface 20a of the second substrate body 21 is disposed on the first side 91a of the release layer 91, wherein the third vias 209 of the first substrate body 20 and the second substrate body 21 correspond to the fourth vias 910 of the release layer 91 for pins 81a of the second pinning fixture 81 to penetrate through the third vias 209 of the first substrate body 20 and the second substrate body 21 that have been separated and the fourth vias 910 of the release layer 91, whereby the first substrate body 20, the second substrate body 21 and the release layer 91 are aligned and stacked via the second pinning fixture 81.

Further, after the second pinning fixture 81 is removed, the first substrate body 20, the second substrate body 21 and the release layer 91 are bonded together using lamination.

In another exemplary embodiment, as shown in FIG. 2H-2, the first substrate body 20, the second substrate body 21 and the release layer 91 may be bonded by roller lamination with the rolling of a roller 70 after the second pinning fixture 81 is removed. Therefore, by bonding the first substrate body 20 and the second substrate body 21 through roller lamination, more fabrication cycle time can be saved.

As shown in FIG. 2I, second patterned wire layers 201b are formed on the second sides 200b of the core layers 200 of the first substrate body 20 and the second substrate body 21. The second patterned wire layers 201b are electrically connected to the conductors 206. Next, second insulation layers 2010 with a plurality of second openings 2010a are formed on the second patterned wire layers 201b. Parts of the second patterned wire layers 201b are exposed through the second openings 2010a.

In this exemplary embodiment, the first metal layers 201 are etched

by a patterning process to form the second patterned wire layers 201b on the second sides 200b of the core layers 200 of the first substrate body 20 and the second substrate body 21.

In an exemplary embodiment, the material used to form the second insulation layers 2010 is an epoxy such as green solder mask or green paint (solder-resist material).

As shown in FIG. 2J, the peripheries of the first substrate body 20, the second substrate body 21 and the release layer 91 are cut off, so as to remove the third vias 209 and the fourth vias 910, and then the first substrate body 20, the second substrate body 21 and the release layer 91 are separated to obtain two package substrates 20′.

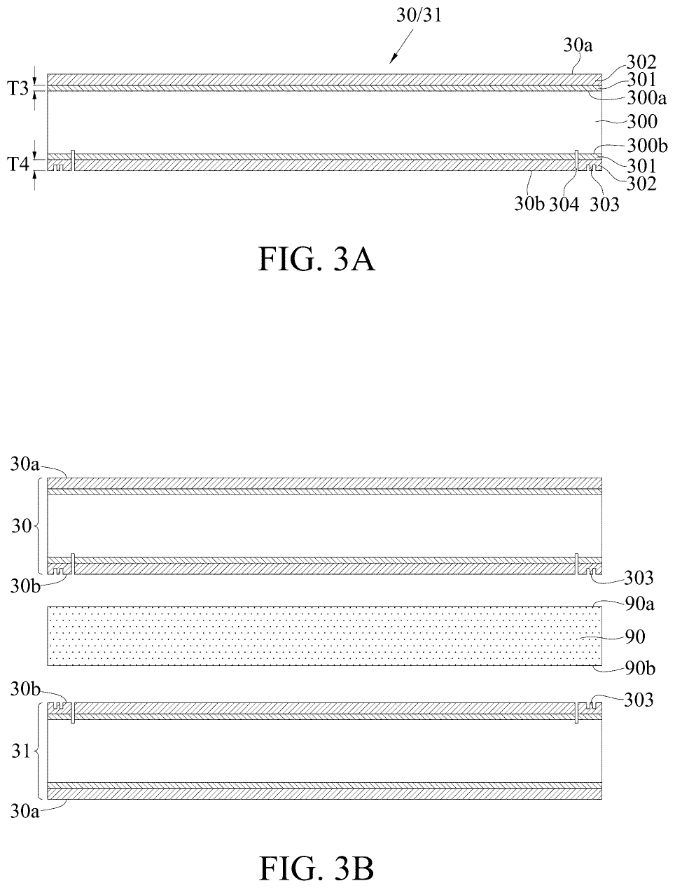

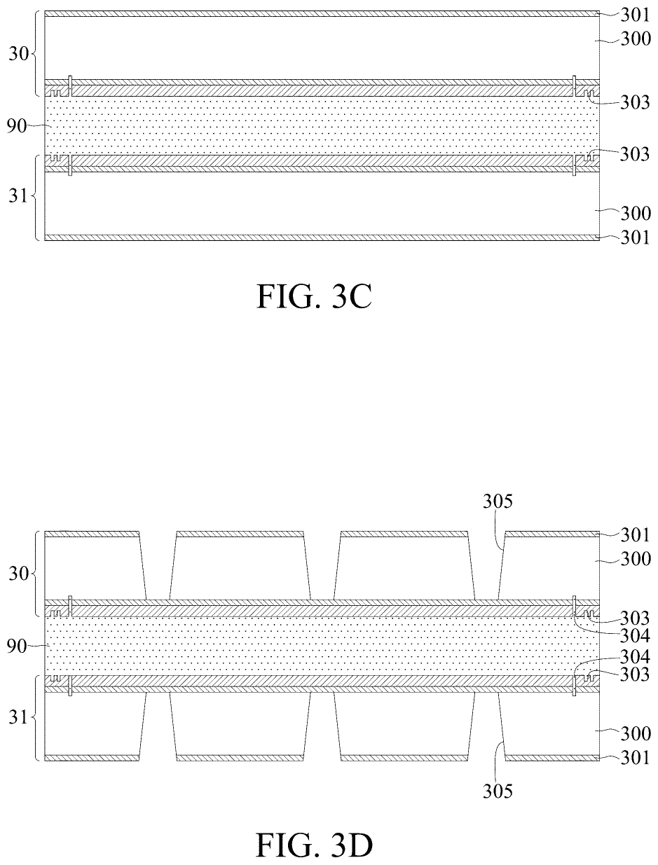

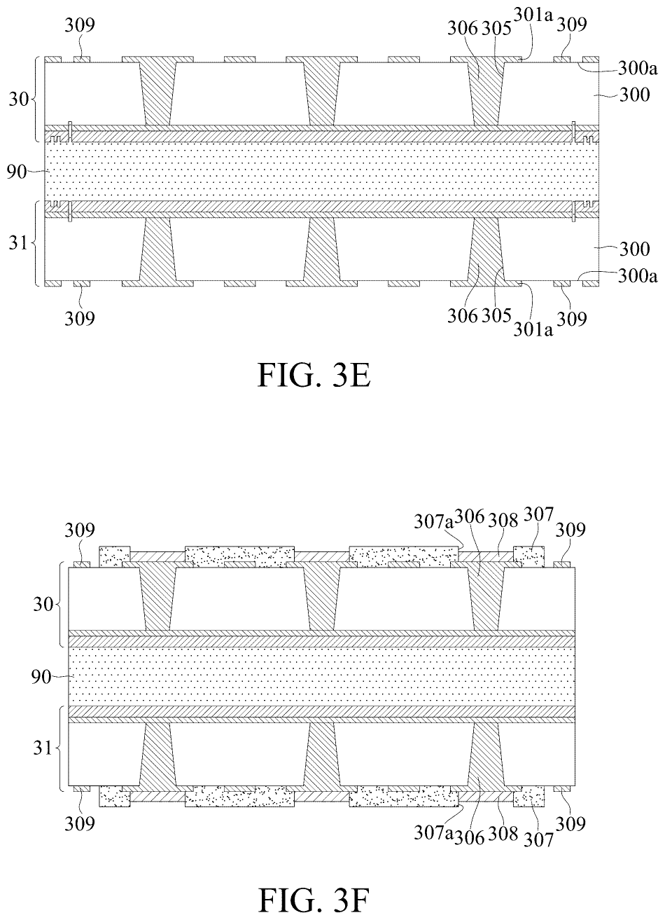

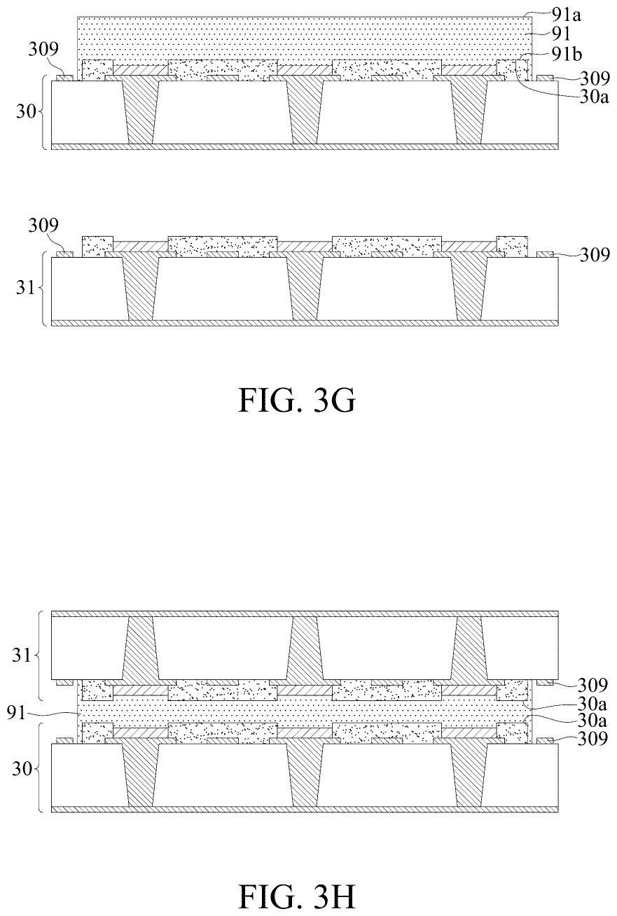

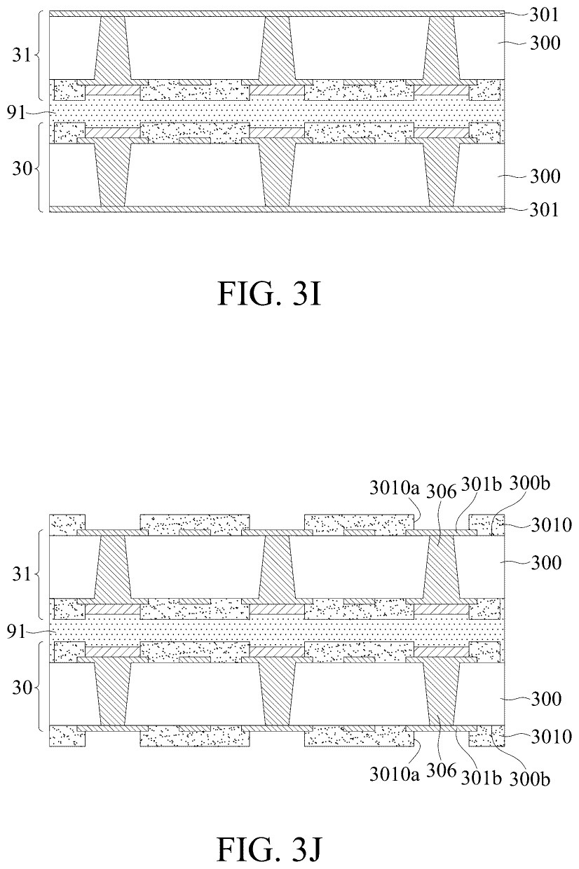

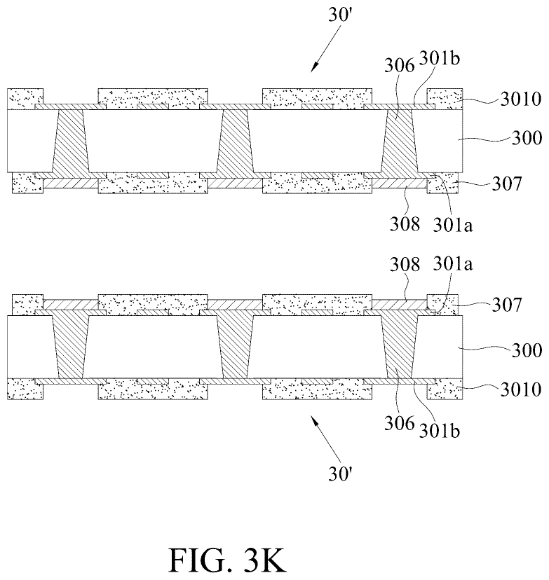

FIG. 3A to FIG. 3K are schematic cross-sectional diagrams illustrating an exemplary method of fabricating package substrate 30′ according to the second embodiment of the present disclosure.

As shown in FIG. 3A, a first substrate body 30 and a second substrate body 31 having first alignment marks 303 and sealed channels 304 are provided.

In this exemplary embodiment, each of the first substrate body 30 and the second substrate body 31 has a first surface 30a and a second surface 30b opposite to the first surface 30a, and includes a core layer 300 having a first side 300a and a second side 300b opposite to the first side 300a, first metal layers 301 formed on the first side 300a and the second side 300b, and second metal layers 302 formed on the first metal layers 301, wherein the core layer 300 is a substrate composed of glass fibers with epoxy, such as a dielectric material such as bismaleimide triazine (BT) or FR5, and the material of the first metal layers 301 and the second metal layers 302 is, for example, copper (Cu).

In an exemplary embodiment, the first alignment marks 303 are formed at the peripheries of the second surfaces 30b of the first substrate body 30 and the second substrate body 31 by etching the second metal layers 302 of the second surfaces 30b. The structures of the first alignment marks 303 may be, for example, recesses or grooves, and may form several alignment structures or annular grooves, but are not limited thereto.

Further, the annular sealed channels 304 are formed at the peripheries of the second surfaces 30b of the first substrate body 30 and the second substrate body 31. The sealed channels 304 are disposed inside the first alignment marks 303. For example, the sealed channels 304 are formed on the second surfaces 30b by laser searing penetrating through the first metal layers 301, the second metal layers 302 and parts of the core layers 300, to enhance the sealing of the first metal layers 301, the second metal layers 302 and the core layers 300 through the sealed channels 304.

In an embodiment, the thickness T3 of the first metal layers 301 is less than the thickness T4 of the second metal layers 302. For example, the thickness T3 of the first metal layers 301 is about 3 μm, and the thickness T4 of the second metal layers 302 is about 18 μm.

As shown in FIG. 3B, a bonding layer 90 having a first side 90a and a second side 90b opposite to the first side 90a is provided, and the first substrate body 30 and the second substrate body 31 are respectively disposed on the first side 90a and the second side 90b of the bonding layer 90.

In an exemplary embodiment, the second surface 30b of the first substrate body 30 is disposed on the first side 90a of the bonding layer 90, while the second surface 30b of the second substrate body 31 is disposed on the second side 90b of the bonding layer 90. The first alignment marks 303 are used as positioning marks or fiducial marks for bonding the first substrate body 30 and the second substrate body 31, wherein the material of the bonding layer 90 may be selected from dielectric materials such as prepreg (PP), Ajinomoto build-up film (ABF), photoimageable dielectric (PID), or polyimide (PI), and the material of the bonding layer 90 is not limited to the above types of materials.

As shown in FIG. 3C, the first substrate body 30, the second substrate body 31 and the bonding layer 90 are bonded, and the second metal layers 302 on the first surfaces 30a of the first substrate body 30 and the second substrate body 31 are removed.

In this exemplary embodiment, a lamination method is utilized to bond the first substrate body 30, the second substrate body 31 and the bonding layer 90. In addition, the bonding layer 90 fills the sealed channels 304 of the first substrate body 30 and the second substrate body 31.

As shown in FIG. 3D, a plurality of blind holes 305 are formed on the first surfaces 30a of the first substrate body 30 and the second substrate body 31.

In this exemplary embodiment, on the first surfaces 30a of the first substrate body 30 and the second substrate body 31, parts of the first metal layers 301 and the core layers 300 are removed by mechanical, laser, etching, or other appropriate means to form the blind holes 305.

As shown in FIG. 3E, a plurality of conductors 306 are formed in the blind holes 305, and then first patterned wire layers 301a are formed on the first sides 300a of the core layers 300 of the first substrate body 30 and the second substrate body 31. The first patterned wire layers 301a are electrically connected to the conductors 306.

In this exemplary embodiment, the conductors 306 are formed in the blind holes 305 by electroplating, and the conductors 306 are formed to be flush with the first metal layers 301, and then the first metal layers 301 are etched by a patterning process to form the first pattered wire layers 301a on the first sides 300a of the core layers 300 of the first substrate body 30 and the second substrate body 31.

In an embodiment, second alignment marks 309, which are formed, for example, as annular metal projections, are formed by etching the first metal layers 301 at the peripheries of the first sides 300a of the core layers 300 of the first substrate body 30 and the second substrate body 31.

As shown in FIG. 3F, first insulation layers 307 with a plurality of first openings 307a are formed on the first patterned wire layers 301a. Parts of the first patterned wire layers 301a are exposed through the first openings 307a. Next, surface treatment layers 308 are formed in the first openings 307a. The surface treatment layers 308 are electrically connected to the first patterned wire layers 301a.

In this exemplary embodiment, the surface treatment layers 308 are formed by electroplating in the first openings 307a of the first insulation layers 307 by means of electroless nickel immersion gold (ENIG), wherein the material forming the surface treatment layers 308 is a nickel-gold alloy (Ni/Au), and the material forming the first insulation layers 307 is an epoxy such as green solder mask or green paint (solder-resist material).

In an exemplary embodiment, peripheries of the first substrate body 20, the second substrate body 21 and the bonding layer 90 are cut by a cutting method, while the second alignment marks 309 are retained.

As shown in FIG. 3G, the bonding layer 90 and the second metal layers 302 on the second surfaces 30b of the first substrate body 30 and the second substrate body 31 are removed, and then a release layer 91 (e.g., a thermal released film or TRF) is formed on the first surface 30a of the first substrate body 30.

As shown in FIG. 3H, the second substrate body 31 is disposed on the release layer 91, whereby the first substrate body 30 and the second substrate body 31 are respectively disposed on a second side 91b and a first side 91a of the release layer 91.

In this exemplary embodiment, the first surface 30a of the second substrate body 31 is disposed on the first side 91a of the release layer 91, whereby the first substrate body 30, the second substrate body 31 and the release layer 91 are stacked according to the second alignment marks 309.

As shown in FIG. 3I, the first substrate body 30, the second substrate body 31 and the release layer 91 are bonded. In this exemplary embodiment, the first substrate body 30, the second substrate body 31 and the release layer 91 are bonded by a lamination method, and then the second alignment marks 309 are removed by cutting off the peripheries of the first substrate body 30 and the second substrate body 31.

As shown in FIG. 3J, second patterned wire layers 301b are formed on the second sides 300b of the core layers 300 of the first substrate body 30 and the second substrate body 31. The second patterned wire layers 301b are electrically connected to the conductors 306, and then second insulation layers 3010 with a plurality of second openings 3010a are formed on the second patterned wire layers 301b. Parts of the second patterned wire layers 301b are exposed through the second openings 3010a.

In this exemplary embodiment, the first metal layers 301 are etched by a patterning process to form the second patterned wire layers 301b on the second sides 300b of the core layers 300 of the first substrate body 30 and the second substrate body 31.

In an exemplary embodiment, the material forming the second insulation layers 3010 is an epoxy such as green solder mask or green paint (solder-resist material).

As shown in FIG. 3K, the first substrate body 30, the second substrate body 31 and the release layer 91 are separated to obtain two package substrates 30′.

Therefore, by setting the alignment marks 303, 309 in this embodiment, there is no need to form the vias 203, 209, 900, 910.

In summary, the exemplary method of fabricating the package substrate of the present disclosure mainly stacks and bonds two thin substrate bodies, namely the first substrate body and the second substrate body, through the bonding layer and the release layer, so as to increase the overall thickness, thereby overcoming the processing limitations of general processing equipment and providing general processing equipment with processing capability. In addition, the first metal layers and the second metal layers are seared by laser to form sealed channels, and the sealing of the edge of the substrates can prevent the substrates from infiltration by chemical solutions in subsequent processes (the infiltration of chemical solutions may cause the risks of short circuits and substrate reliability).

While some of the embodiments of the present disclosure have been described in detail above, it is, however, possible for those of ordinary skill in the art to make various modifications and changes to the exemplary embodiments shown without substantially departing from the teaching and advantages of the present disclosure. Such modifications and changes are encompassed in the spirit and scope of the present disclosure as set forth in the appended claims.

What is claimed is:

1. A method of fabricating a package substrate, comprising:
providing a bonding layer, a first substrate body and a second substrate body, wherein each of the first substrate body and the second substrate body has a first surface and a second surface opposite to the first surface;
disposing the first substrate body and the second substrate body on both sides of the bonding layer by the second surface of the first substrate body and the second surface of the second substrate body, respectively;
forming a plurality of conductors in the first substrate body and the second substrate body;
forming a first patterned wire layer on each of the first surfaces of the first substrate body and the second substrate body, wherein the first patterned wire layers are electrically connected to the plurality of conductors;
separating the first substrate body, the second substrate body and the bonding layer;
bonding the first substrate body and the second substrate body to two opposite sides of a release layer via the first surface of the first substrate body and the first surface of the second substrate body, respectively;
forming a second patterned wire layer on each of the second surfaces of the first substrate body and the second substrate body, wherein the second patterned wire layers are electrically connected to the plurality of conductors; and
separating the first substrate body, the second substrate body and the release layer to obtain the package substrates.

2. The method of claim 1, wherein each of the first substrate body and the second substrate body comprises a core layer, first metal layers formed on both sides of the core layer, and second metal layers formed on the first metal layers.

3. The method of claim 2, further comprising searing the first metal layers, the second metal layers and parts of the core layers at peripheries of the second surfaces of the first substrate body and the second substrate body to form a sealed channel.

4. The method of claim 1, further comprising forming a plurality of first vias at peripheries of the first substrate body and the second substrate body, and forming a plurality of second vias at peripheries of the bonding layer corresponding to positions of the plurality of first vias, so as to penetrate through the plurality of first vias and the plurality of second vias by means of pins of a pinning fixture, in order to dispose the first substrate body and the second substrate body on the both sides of the bonding layer by the second surface of the first substrate body and the second surface of the second substrate body, respectively.

5. The method of claim 3, further comprising forming a plurality of first vias at peripheries of the first substrate body and the second substrate body outside the sealed channel, and forming a plurality of second vias at peripheries of the bonding layer corresponding to positions of the plurality of first vias, so as to penetrate through the plurality of first vias and the plurality of second vias by means of pins of a pinning fixture, in order to dispose the first substrate body and the second substrate body on the both sides of the bonding layer by the second surface of the first substrate body and the second surface of the second substrate body, respectively.

6. The method of claim 1, wherein the step of bonding the first substrate body and the second substrate body that are separated to the both sides of the release layer by the first surface of the first substrate body and the first surface of the second substrate body respectively comprises forming a plurality of third vias at peripheries of the first substrate body and the second substrate body, and forming a plurality of fourth vias at peripheries of the release layer corresponding to positions of the plurality of third vias, so as to penetrate through the plurality of third vias and the plurality of fourth vias by means of pins of a pinning fixture, in order to bond the release layer and the first substrate body and the second substrate body that are separated.

7. The method of claim 6, further comprising laminating the release layer and the first substrate body and the second substrate body that are separated by the release layer.

8. The method of claim 7, wherein the laminating is performed by a roller to laminate the release layer and the first substrate body and the second substrate body that are separated by the release layer.

9. The method of claim 1, further comprising forming a plurality of first alignment marks at peripheries of the second surfaces of the first substrate body and the second substrate body for disposing the first substrate body and the second substrate body on both sides of the bonding layer by the second surface of the first substrate body and the second surface of the second substrate body, respectively.

10. The method of claim 9, wherein the plurality of first alignment marks are used as positioning marks for bonding the first substrate body and the second substrate body.

11. The method of claim 3, further comprising forming a plurality of first alignment marks at peripheries of the second surfaces of the first substrate body and the second substrate body outside the sealed channel for disposing the first substrate body and the second substrate body on both sides of the bonding layer by the second surface of the first substrate body and the second surface of the second substrate body, respectively.

12. The method of claim 11, wherein the plurality of first alignment marks are used as positioning marks for bonding the first substrate body and the second substrate body.

13. The method of claim 1, further comprising after forming the first patterned wire layer on the first surface of each of the first substrate body and the second substrate body, forming a plurality of second alignment marks at peripheries of the first surfaces of the first substrate body and the second substrate body for disposing the first substrate body and the second substrate body that are separated on the both sides of the release layer by the first surface of the first substrate body and the first surface of the second substrate body, respectively.

14. The method of claim 13, wherein the plurality of second alignment marks are used as positioning marks for bonding the first substrate body and the second substrate body, so as to stack the first substrate body and the second substrate body on the both sides of the release layer by the first surface of the first substrate body and the first surface of the second substrate body, respectively, and then laminate the release layer and the first substrate body and the second substrate body that are separated.

15. The method of claim 1, further comprising forming a first insulation layer having a plurality of openings on each of the first patterned wire layers, wherein parts of the first patterned wire layers are exposed from the plurality of openings.

16. The method of claim 15, further comprising forming a surface treatment layer on each of the first patterned wire layers exposed from the plurality of openings of the first insulation layers.

17. The method of claim 1, further comprising forming a second insulation layer having a plurality of openings on each of the second patterned wire layers, wherein parts of the second patterned wire layers are exposed from the plurality of openings.
